(19) United States
(12) Patent Application Publication
(10) Pub. No.: US 2023/0120403 A1
(43) Pub. Date: Apr. 20, 2023

(54) HEAT DISSIPATION DEVICE AND PROJECTOR HAVING A PHOSPHOR LAYER

(71) Applicant: Young Optics Inc., Hsinchu (TW)

(72) Inventor: Jia-Bin Huang, Hsinchu (TW)

(73) Assignee: Young Optics Inc., Hsinchu (TW)

(21) Appl. No.: 18/085,586

(22) Filed: Dec. 21, 2022

Related U.S. Application Data
(63) Continuation of application No. 16/672,498, filed on Nov. 3, 2019.

(30) Foreign Application Priority Data
Nov. 5, 2018 (TW) 107139173

(51) Int. Cl. G03B 21/16; F21K 9/64; H01L 33/64; H10N 10/17

(52) U.S. Cl. CPC G03B 21/16; F21K 9/64; H01L 33/645; H01L 35/32

(57) ABSTRACT

A heat dissipation device including two insulation layers, two metal layers, a semiconductor layer, and a phosphor layer is provided. The semiconductor layer is disposed between the two metal layers, and the whole of the semiconductor and the two metal layers is disposed between the two insulation layers. The phosphor layer is disposed on one of the insulation layers. A projector is also provided.

### CROSS-REFERENCE TO RELATED APPLICATION

This application is a continuation application of and claims the priority benefit of U.S. application Ser. No. 16/672,498, filed on Nov. 3, 2019, which claims the priority benefit of Taiwan application serial no. 107139173, filed on Nov. 5, 2018. The entirety of each of the above-mentioned patent applications is hereby incorporated by reference herein and made a part of this specification.

### BACKGROUND OF THE INVENTION

### Field of the Invention

The invention relates to an optical device. More particularly, the invention relates to a heat dissipation device and a projector.

### Description of Related Art

The existing green light-emitting diode (LED) has insufficient light-emitting efficiency; hence, the green beam is mostly generated by irradiating phosphor by a blue beam, a UV beam, or another light source with short-wavelength as an excitation light, so that the phosphor is excited to form the green beam. Generally, the conversion efficiency of the phosphor is proportional to the energy density of the excitation light received by the phosphor, and the higher the energy density of the light, the higher the temperature of the light. However, the service life of the phosphor is inversely proportional to the operating temperature of the phosphor. At present, it is common to coat a phosphor layer onto a substrate, connect the substrate to a heat dissipation fin, and blow the heat dissipation fin to dissipate the heat. However, due to the thermal resistance of the substrate, heat energy cannot be transmitted to the fin effectively and rapidly on a large scale; thereby, the operating temperature of the phosphor layer is still high.

In a conventional projector, a combination of a rotating phosphor wheel and a color wheel is applied to generate beams of different colors, so as to allow the projector to project a color image; at the same time, the rotation of the phosphor wheel contributes to the decrease in the operating temperature of the phosphor layer. Nevertheless, motor driving parts is utilized for rotating the phosphor wheel and the color wheel may deteriorate the reliability of the system, so that the system life time cannot be effectively extended.

### SUMMARY OF THE INVENTION

The invention provides a heat dissipation device with long service lifetime and high heat dissipation efficiency.

The invention provides a projector with high reliability and long service lifetime.

An embodiment of the invention provides a heat dissipation device including two insulation layers, two metal layers, a semiconductor layer, and a phosphor layer. The semiconductor layer is disposed between the two metal layers, and the whole of the semiconductor layer and the two metal layers are disposed between the two insulation layers. The phosphor layer is disposed on one of the insulation layers.

An embodiment of the invention provides a heat dissipation device including a thermoelectric cooling chip and a phosphor layer. The thermoelectric cooling chip has a ceramic surface, and the phosphor layer is sintered on the ceramic surface.

An embodiment of the invention provides a projector including an optical engine, a light valve, and a lens assembly. The optical engine includes a collimated light source, a lens, an insulation substrate, and a thermoelectric cooling chip. The lens is disposed at a downstream of a light path of the collimated light source, the insulation substrate is disposed at a downstream of a light path of the lens, and a phosphor layer is disposed on one side of the insulation substrate. The thermoelectric cooling chip is disposed on the other side of the insulation substrate. The light valve is disposed at a downstream of a light path of the optical engine, and the lens assembly is disposed at a downstream of a light path of the light valve.

In the heat dissipation device and the projector provided in one or more embodiments of the invention, the thermoelectric cooling chip or a semiconductor thermoelectric cooling (TEC) technology is employed to assist in the heat dissipation of the phosphor layer; therefore, the heat dissipation device can have long service life and high heat dissipation efficiency, and the projector can have high reliability and long service life.

To make the above features and advantages provided in one or more of the embodiments more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view illustrating a light path of a projector according to an embodiment of the invention.

FIG. 2 is a schematic cross-sectional view illustrating the heat dissipation device depicted in FIG. 1.

FIG. 3 is a schematic cross-sectional view illustrating a heat dissipation device according to another embodiment of the invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

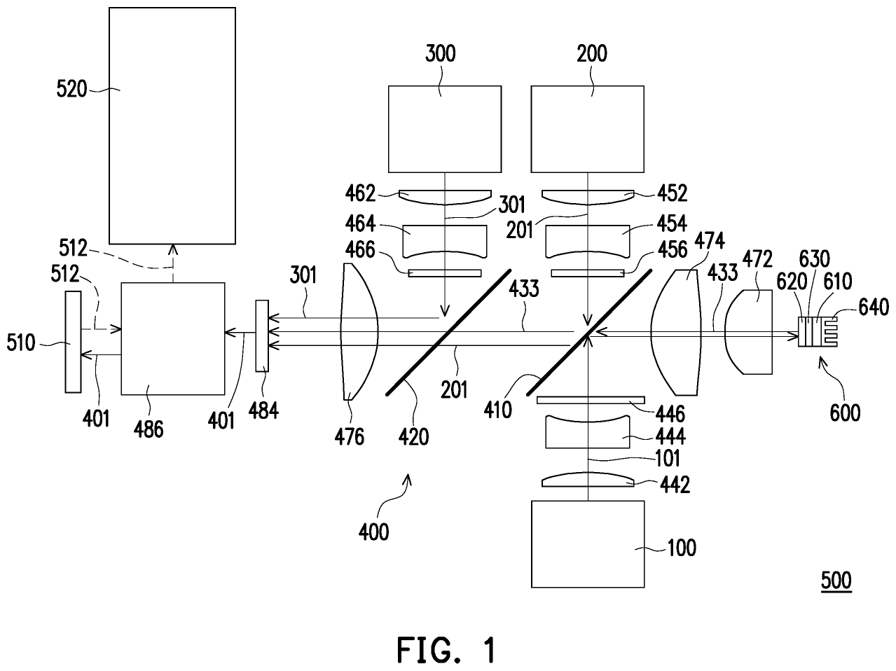

FIG. 1 is a schematic view illustrating a light path of a projector according to an embodiment of the invention. For instance, in the heat dissipation structure of a phosphor layer in a projector provided in an embodiment, a thermoelectric cooling chip is applied to assist in heat dissipation of the phosphor layer, whereby good heat dissipation effects can be achieved, the operating temperature of the phosphor layer can be reduced, and the service life of the phosphor layer can be extended. Besides, driving parts including a rotatable phosphor wheel can be selectively omitted, and therefore the reliability and the service life of the projector can be improved. The design of the projector provided herein is explained hereinafter.

Please refer to FIG. 1, a projector 500 provided in the present embodiment includes an optical engine 400, a light valve 510, and a projection lens 520.

In the present embodiment, the optical engine 400 includes light source sets 100, 200, and 300, lenses 442, 444, 472, 474, 452, 454, 464, and 476, a heat dissipation device 600, a beam splitter 410, a beam splitter 420, diffusers 446, 456, and 466, a light homogenizing element 484, and a prism 486.

Each of the light source sets 100, 200, and 300 may be a collimated light source capable of outputting a collimated beam and may be a laser light source or may be collimated by various optical elements, for example, an LED or another conventional light source. Namely, the light source sets 100, 200, and 300 may include a non-collimated light source and at least one optical element, for example, a collimating lens. According to the present embodiment, each of the light source sets 100, 200, and 300 may include a laser bank which includes a laser diode array. Besides, as to the design of the light source sets 100, 200, and 300 in the present embodiment, the structures of the light source sets 100, 200, and 300 are substantially the same, while the colors of the light-emitting elements in the light source sets 100, 200, and 300 are different and the powers thereof are slightly different. However, the invention is not limited thereto. In the present embodiment, the light source sets 100, 200, 300 can respectively output a blue beam 101, another blue beam 201, and a red beam 301. When the light source sets 100, 200, and 300 are being applied, and the power consumed thereby is respectively more than or equal to 20 watts, 50 watts, or 100 watts and less than or equal to 300 watts, the efficiency and the heat dissipation effects can be balanced to a better extent.

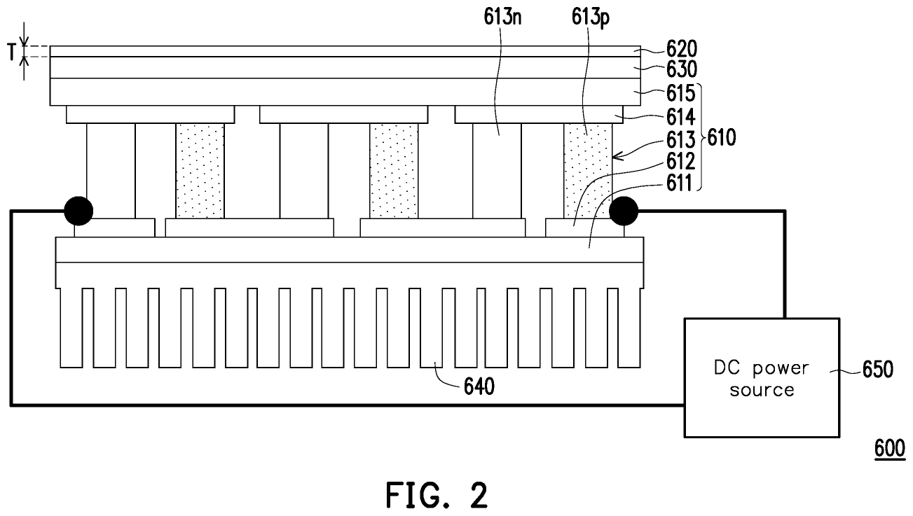

FIG. 2 is a schematic cross-sectional view illustrating the heat dissipation device depicted in FIG. 1. The heat dissipation device 600 may be a fixed wavelength conversion element and is not a rotatable device of, for example, a color wheel or a phosphor wheel. In the present embodiment, the heat dissipation device 600 includes a thermoelectric cooling chip 610, a phosphor layer 620, an insulation substrate 630, a heat sink 640, and a direct current (DC) power source 650. The thermoelectric cooling chip 610 is, for instance, a thermoelectric cooler (TEC) that includes insulation layers 611 and 615, metal layers 612 and 614, and a semiconductor layer 613. The insulation layers 611 and 615 are, for instance, ceramic substrates. The semiconductor layer 613 includes a plurality of pairs of semiconductor pillars, and each of the semiconductor pillars includes a p-type semiconductor pillar 613p and an n-type semiconductor pillar 613n. The insulation substrate 630 is, for instance, a fixed ceramic substrate and is not a rotating disk or a movable substrate. Besides, the phosphor layer 620 may include phosphor of various colors, for example, the phosphor capable of being excited to form a red beam or a green beam with a longer wavelength after absorbing the blue beam or the UV beam with a shorter wavelength. In the present embodiment, the phosphor layer 620 is capable of being excited by the blue beam to emit the green beam. A thickness T of the phosphor layer 620 may be less than or equal to 1 mm, for example, less than or equal to 0.1 mm, 0.3 mm, or 0.5 mm. The phosphor layer 620 may be formed by merely sintering ceramic phosphor or formed after being mixed with resin or another carrier, which should however not be construed as a limitation to the invention. According to the present embodiment, the phosphor layer 620 is a ceramic phosphor layer directly sintered on the surface of the insulation substrate 630. The DC power source 650 is capable of supplying electrical power to the semiconductor pillars. Besides, the heat sink 640 is, for instance, heat dissipation fins.

The beam splitter 410 and the beam splitter 420 may be dichroic mirrors, x-shaped beam combiners, a beam combining prism set, polarizing beam splitters (PBSs), and so on respectively. In the present embodiment, the beam splitter 410 and the beam splitter 420 are two substantially parallel dichroic mirrors and are capable of reflecting beams having a specific wavelength range and allowing beams having other wavelength ranges to pass through. For instance, the beam splitter 410 is capable of reflecting the blue beam and allowing the green beam to pass through, and the beam splitter 420 is capable of reflecting the red beam and allowing the blue beam and the green beam to pass through.

The diffusers 446, 456, and 466 are widely used optical elements and maybe optical films or elements having diffusion particles or diffusion micro-structures. The diffusers 446, 456, and 466 can be applied to increase the divergence angle of each beam for reducing the speckle phenomenon of laser beam. Note that the diffusers 446, 456, and 466 are not limited to be of a sheet-like shape. Additionally, the diffusers contribute to the expansion of a diffusion angle of each incident beam, so that the light spots of the beam can evenly irradiate the phosphor layer.

In the present embodiment, the light homogenizing element 484 may be a light integration rod, a lens array, a fly-eye lens, or another optical element capable of homogenizing the beam. The light homogenizing element 484 provided in the present embodiment is a fly-eye lens.

The optical element 486 may be a field lens, a prism, a reflective mirror, or the like. In the present embodiment, the optical element 486 is a total internal reflection (TIR) prism set and may be replaced by a reverse total internal reflection (RTIR) prism set according to the actual design.

The light valve 510 is a widely used element and is a type of spatial light modulator (SLM) that can be configured to convert an illumination beam into an image beam. The light valve 510 may be a digital micro-mirror device (DMD), a liquid crystal on silicon (LCoS) panel, or a liquid crystal display (LCD) panel. In the present embodiment, the light valve 510 is a DMD.

The projection lens 520 is, for instance, configured for imaging and may include at least one lens. According to the present embodiment, the projection lens 520 sequentially includes a front lens group, an aperture, and a rear lens group, and the front lens group and the rear lens group each include two or more lenses having refractive power. In the present embodiment, the number of the lenses having refractive power in the projection lens 520 is less than or equal to 15.

The relative position of each element and the way to operate the element will be described below.

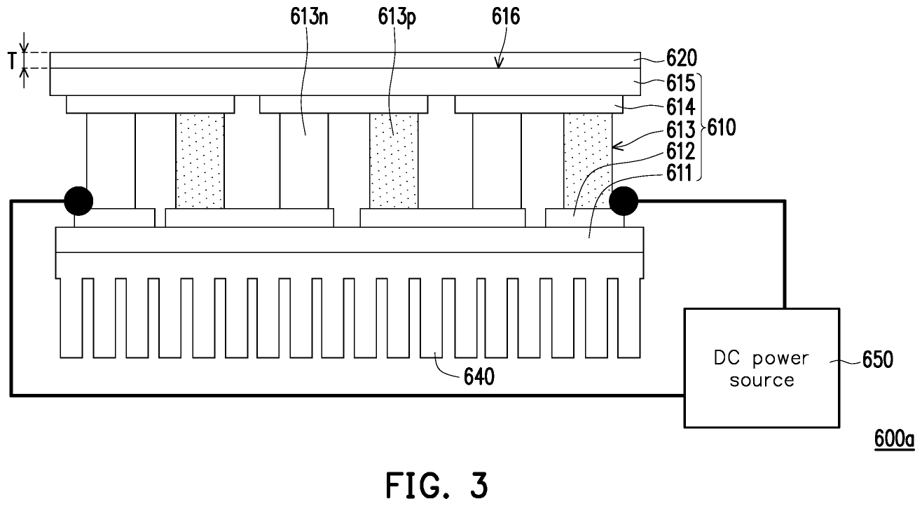

In the thermoelectric cooling chip 610 of the heat dissipation device 600, the metal layer 612 is disposed on the insulation layer 611, the semiconductor layer 613 is disposed on the metal layer 612, the metal layer 614 is disposed on the semiconductor layer 613, and the insulation layer 615 is disposed on the metal layer 614. Besides, the phosphor layer 620 is thermally coupled to the insulation layer 615. In the present embodiment, the phosphor layer 620 is disposed on one side of the insulation substrate 630, and the thermoelectric cooling chip 610 is disposed on the other side of the insulation substrate 630. That is, the phosphor layer 620 is thermally coupled to the insulation layer 615 through the insulation substrate 630; namely, the phosphor layer 620 is disposed on the insulation layer 615 through the insulation substrate 630. The phosphor layer 620 may be coated or sintered onto the insulation substrate 630. However, in a heat dissipation device 600a provided in another embodiment, as shown in FIG. 3, the thermoelectric cooling chip 610 has a ceramic surface 616, i.e., the surface of the insulation layer 615, and the phosphor layer 620 is sintered, thermally cured, or coated onto the ceramic surface 616. In other words, the phosphor layer 620 is directly disposed on the insulation layer 615 and is directly thermally coupled to the insulation layer 615.

Besides, the thermoelectric cooling chip 610 is disposed on the heat sink 640 and located between the phosphor layer 620 and the heat sink 640. In the present embodiment, the semiconductor pillars are electrically connected through the metal layer 612 and the metal layer 614. According to the present embodiment, the current provided by the DC power source 650 flows through the semiconductor pillars via the metal layer 612 and the metal layer 614, so that an upper side of the thermoelectric cooling chip 610 (i.e., the side of the insulation layer 615) becomes a cold side, and a lower side of the thermoelectric cooling chip 610 (i.e., the side of the insulation layer 611) becomes a hot side. In other words, the phosphor layer 620 is disposed on the cold side of the thermoelectric cooling chip 610, and the heat sink 640 is disposed on the hot side of the thermoelectric cooling chip 610. Owing to the configuration of the thermoelectric cooling chip 610, the heat energy of the phosphor layer 620 can be rapidly transmitted to the heat sink 640 and can then be dissipated into the environment from the heat sink 640.

The beam splitter 410 is disposed at a downstream of a light path of the light source set 100, the light source set 200, and the heat dissipation device 600, and the beam splitter 420 is disposed at a downstream of a light path of the light source 300 and a downstream of a light path of the beam splitter 410.

In the present embodiment, when the blue beam 101 emitted from the light source set 100 is transmitted to the beam splitter 410, the blue beam 101 is reflected by the beam splitter 410 to the phosphor layer 620, so that a green beam 433 is excited. After the green beam 433 is transmitted back to the beam splitter 410, the green beam 433 passes through the beam splitter 410.

In the present embodiment, the beam splitter 410 reflects the blue beam 201 emitted from the laser light source set 200 to the beam splitter 420 and allows the green beam 433 coming from the phosphor layer 620 to pass through, so that the green beam 433 is transmitted to the beam splitter 420. The beam splitter 420 reflects the red beam 301 emitted from the light source 300 and allows the beam 201 emitted from the light source set 200 and reflected by the beam splitter 410 and the beam 433 coming from the phosphor layer 620 to pass through. Thereby, the red beam 301, the green beam 433, and the blue beam 201 can be combined by the beam splitter 420 into an illumination beam 401.

After the illumination beam 401 coming from the beam splitter 420 is homogenized and shaped by the light homogenizing element 484, the illumination beam 401 irradiates the light valve 510 via the prism 486. The light valve 510 modulates the illumination beam 401 into an image beam 512, and the image beam 512 is transmitted to the projection lens 520 via the prism 486. The projection lens 520 projects the image beam 512 onto an imaging plane (where a screen is arranged, for instance), so as to form an image frame. In the present embodiment, the light source sets 100, 200, and 300 may emit light at the same time or in turn, so that the illumination beam 401 simultaneously or in turn appears to be red, green, blue, or of any other combination of said colors, for example, white, so as to form a color image in no need of any driving part, for example, a color wheel or a phosphor wheel. Thereby, the issue of the reduced reliability caused by the use of the driving parts at the light source can be prevented in the projector 500 provided in the present embodiment, and the issue of loss of optical energy in gaps among the regions of different colors in the color wheel can be prevented as well.

Besides, although it is easy to concentrate the heat energy in a fixed location if no driving part (for example, the rotatable phosphor wheel) is used, the heat energy can be rapidly transmitted to the heat sink 640 via the thermoelectric cooling chip 610 according to an embodiment of the invention, so as to effectively reduce heat accumulation on the phosphor layer 620. Thereby, the phosphor layer 620 can have a relatively lower operating temperature, and the service life of the phosphor layer 620 can thus be extended. As such, the heat dissipation device 600 and the projector 500 provided in one or more embodiments of the invention can have long service life and high heat dissipation efficiency.

Specifically, in the embodiment shown in FIG. 2, the phosphor layer 620 is formed on the insulation substrate 630 (for example, a heat resistant ceramic substrate), and the insulation substrate 630 is then disposed on the cold side of the thermoelectric cooling chip 610. The thermoelectric cooling chip 610 is able to effectively reduce the temperature on one side of the insulation substrate 630 to be lower than the room temperature, so as to effectively improve the heat conduction efficiency of the insulation substrate 630. On the other hand, according to the present embodiment, no light-emitting element (for example, light-emitting diode) is disposed between the phosphor layer 620 and the ceramic substrate 630; alternatively, it may be understood that any part of the phosphor layer 620 does not include any light-emitting element that is already coupled to the light source and can convert electrical energy into optical energy after receiving a signal.

In the embodiment depicted in FIG. 3, the phosphor layer 620 is directly sintered, thermally cured, or formed and fixed in another known manner onto the surface of the thermoelectric cooling chip 610; since the thermal resistance of the insulation substrate 630 no longer exists, the thermoelectric cooling chip 610 is able to effectively transmit the heat energy of the phosphor layer 620 to the heat sink 640.

According to an embodiment, to ensure the sufficient intensity of the beam 433 emitted by the phosphor layer 620, the power of the beam 101 irradiating the phosphor layer 620 can be 20 watts, 50 watts, or 100 watts or more and 1000 watts or less. In the present embodiment, due to the issue of electro-optical conversion efficiency, the power of the beam irradiating the phosphor layer 620 is less than the power consumed by the light source set 100. On the other hand, generally, if the power of the beam irradiating the phosphor layer 620 is greater than 40 watts, the temperature of the phosphor layer cannot be effectively reduced in consideration of the thermal resistance, even though a fan is applied to dissipate the heat of the heat sink. However, in the embodiment shown in FIG. 2 and FIG. 3, the thermoelectric cooling chip 610 is applied; therefore, the thermal resistance can be minimized, and the aforementioned issue of ineffective heat dissipation can be solved, whereby the reliability and the service life of the projector 500 can be effectively improved. Moreover, a fan may be selectively disposed on another side of the heat sink opposite to the heat source, so as to further enhance the heat dissipation effects.

In the present embodiment, the diffuser 446 is disposed on the light path between the light source set 100 and the beam splitter 410, the diffuser 456 is disposed on the light path between the light source set 200 and the beam splitter 410, and the diffuser 466 is disposed on the light path between the light source 300 and the beam splitter 420. The diffusers 446, 456, and 466 can better homogenize the beams 101, 201, and 301, so as to reduce the speckle phenomenon generated by the laser beam.

In the present embodiment, the lenses 442 and 444 are sequentially disposed on a light path between the light source set 100 and the diffuser 446, i.e., at a downstream of a light path of the light source set 100, and the insulation substrate 630 is disposed at a downstream of a light path of the lenses 422 and 444. The lenses 472 and 474 are disposed on a light path between the wavelength conversion element 430 and the beam splitter 410, the lenses 452 and 454 are sequentially disposed on a light path between the light source set 200 and the diffuser 456, the lenses 462 and 464 are sequentially disposed on a light path between the light source 300 and the diffuser 466, and the lens 476 is disposed on a light path between the beam splitter 420 and the light homogenizing element 484. These lenses are capable of providing a beam condensing function or a function of changing the cone angle of the beam.

In the thermoelectric cooling chip 610 provided in the present embodiment, the insulation layer 611 and the insulation layer 615 are, for instance, a first insulation layer and a second insulation layer, and the metal layer 612 and the metal layer 614 are, for instance, a first metal layer and a second metal layer.

To sum up, in the heat dissipation device and the projector provided in one or more embodiments of the invention, the thermoelectric cooling chip or a semiconductor TEC technology is employed to assist in the heat dissipation of the phosphor layer; therefore, the heat dissipation device can have long service life and high heat dissipation efficiency, and the projector can have high reliability and long service life.

It will be apparent to those skilled in the art that various modifications and variations can be made to the structure described in the disclosure without departing from the scope or spirit of the disclosure. In view of the foregoing, it is intended that the disclosure cover modifications and variations provided they fall within the scope of the following claims and their equivalents.

What is claimed is:

1. A heat dissipation device comprising:
a thermoelectric cooling chip having a ceramic surface; and
a phosphor layer directly sintered on the ceramic surface of the thermoelectric cooling chip, wherein the ceramic surface is fixed and stationary, and the phosphor layer and the thermoelectric cooling chip belong to different layers.

2. The heat dissipation device according to claim 1, wherein the phosphor layer is directly disposed on a surface of the thermoelectric cooling chip.

3. The heat dissipation device according to claim 1, further comprising a ceramic substrate, wherein the phosphor layer is disposed on a surface of the thermoelectric cooling chip through the ceramic substrate, and no light-emitting element is disposed between the phosphor layer and the ceramic substrate.

4. The heat dissipation device according to claim 3, further comprising a heat sink, wherein the thermoelectric cooling chip is disposed on the heat sink, and the thermoelectric cooling chip is located between the phosphor layer and the heat sink.

5. The heat dissipation device according to claim 3, wherein a thickness of the phosphor layer is less than 1 mm.

6. The heat dissipation device according to claim 1, wherein the thermoelectric cooling chip comprises:
a first insulation layer;
a first metal layer disposed on the first insulation layer;
a semiconductor layer disposed on the first metal layer;
a second metal layer disposed on the semiconductor layer; and
a second insulation layer disposed on the second metal layer, wherein the ceramic surface is a surface of the second insulation layer.

7. The heat dissipation device according to claim 6, wherein the semiconductor layer comprises a plurality of pairs of semiconductor pillars, each of the semiconductor pillars comprises a p-type semiconductor pillar and an n-type semiconductor pillar, and the pairs of semiconductor pillars are electrically connected through the first metal layer and the second metal layer.

8. A projector comprising:
an optical engine comprising:
a first collimated light source;
a lens disposed at a downstream of a light path of the first collimated light source;
a phosphor layer disposed at a downstream of a light path of the lens, wherein the phosphor layer is fixed and stationary with respect to the first collimated light source;
a thermoelectric cooling chip, wherein the phosphor layer is directly sintered on the thermoelectric cooling chip;
a second collimated light source;
a third collimated light source;
a first beam splitter disposed at downstreams of light paths of the first collimated light source, the second collimated light source, and the phosphor layer; and
a second beam splitter disposed at downstreams of light paths of the third collimated light source and the first beam splitter;
a light valve disposed at a downstream of a light path of the optical engine; and
a lens assembly disposed at a downstream of a light path of the light valve,
wherein the phosphor layer is disposed at a cold side of the thermoelectric cooler, and a power consumption rate of the first collimated light source is greater than or equal to 50 watts.

9. The projector according to claim 8, wherein a sum of the power of the first collimated light source, a power of the second collimated light source, and a power of the third collimated light source ranges from 200 watts to 1000 watts.

10. The projector according to claim 8, wherein the phosphor layer is directly sintered on a ceramic surface of the thermoelectric cooling chip.

11. The projector according to claim 8, wherein thermoelectric cooling chip is fixed and stationary with respect to the first collimated light source.

12. The projector according to claim 8 further comprising a heat sink, wherein the thermoelectric cooling chip is disposed on the heat sink, and the thermoelectric cooling chip is located between the phosphor layer and the heat sink.

13. The projector according to claim 12, wherein a thickness of the phosphor layer is less than 1 mm.

14. The projector according to claim 8, wherein the thermoelectric cooling chip comprises:
a first insulation layer;
a first metal layer disposed on the first insulation layer;
a semiconductor layer disposed on the first metal layer;
a second metal layer disposed on the semiconductor layer; and
a second insulation layer disposed on the second metal layer, wherein the phosphor layer is disposed on a surface of the second insulation layer.

15. The projector according to claim 14, wherein the semiconductor layer comprises a plurality of pairs of semiconductor pillars, each of the semiconductor pillars comprises a p-type semiconductor pillar and an n-type semiconductor pillar, and the pairs of semiconductor pillars are electrically connected through the first metal layer and the second metal layer.

16. The projector according to claim 8, wherein the first collimated light source is capable of emitting a blue beam, the phosphor layer is capable of converting the blue beam into a green beam, the second collimated light source is capable of emitting another blue beam, and the third collimated light source is capable of emitting a red beam.

17. The projector according to claim 16, wherein the first beam splitter is capable of reflecting the blue beam and the another blue beam and allowing the green beam to pass through, and the second beam splitter is capable of reflecting the red beam and allowing the blue beam and the green beam to pass through.

18. The projector according to claim 8, wherein the first beam splitter and the second beam splitter are substantially parallel to each other.

19. The projector according to claim 8, wherein the first beam splitter and the second beam splitter are dichroic mirrors.

20. The projector according to claim 8, wherein the optical engine further comprises:
a first diffuser disposed on a light path between the first collimated light source and the first beam splitter;
a second diffuser disposed on a light path between the second collimated light source and the first beam splitter; and
a third diffuser disposed on a light path between the third collimated light source and the second beam splitter.
